(19) United States
(12) Patent Application Publication
(10) Pub. No.: US 2026/0205074 A1
(43) Pub. Date: Jul. 16, 2026

(54) Novel Chopper-Stabilized Correlated Double Sampling Multi-path Amplifier Circuit and Method Based on Miller Capacitor Reuse

(71) Applicant: Xiamen University, Xiamen (CN)

(72) Inventor: Xiaochao Li, Xiamen (CN)

(21) Appl. No.: 19/449,758

(22) Filed: Jan. 15, 2026

(30) Foreign Application Priority Data
Jan. 16, 2025 (CN) 2025100703217

(51) Int. Cl. H03F 3/387

(52) U.S. Cl. CPC H03F 3/387; H03F 2200/375; H03F 2200/459

(57) ABSTRACT

A novel chopper-stabilized correlated double sampling multi-path amplifier circuit and method based on Miller capacitor reuse are disclosed, relating to integrated circuit design. The circuit and method exploit the Miller compensation capacitors as the correlated double sampling elements, which inherently provide discrete-time high-pass filter on DC offset, thereby not only maintaining the stability but also suppressing the offset, noise, and output ripple. Compared with conventional correlated double sampling circuits, the disclosed circuit reduces one set of sampling capacitors and sampling switches. Furthermore, the high-pass characteristic of the novel correlated double sampling circuit effectively suppresses output ripple and mitigates 1/f noise without requiring the large capacitors and resistors used in the high-pass filter of conventional chopper-stabilized multi-path amplifier designs. Consequently, the disclosed circuit and method achieve improvements in input-referred offset, input-referred noise spectral density, and input-referred ripple, while simplifying the circuit architecture, reducing layout area, and lowering power consumption.

This application claims the priority benefit of China application serial no. CN202510070321.7, filed on Jan. 16, 2025. The entirety of the above-mentioned patent application is hereby incorporated by reference herein and made a part of this specification.

### FIELD OF THE INVENTION

The invention relates to the field of mixed-signal integrated circuit design, and specifically to amplifier circuits that combine analog circuit with calibration techniques. In particular, the invention provides a novel chopper-stabilized correlated double sampling multi-path amplifier circuit and method with low offset, low output ripple, and low input-referred noise spectral density.

### BACKGROUND

A chopper-stabilized multi-path amplifier is a circuit architecture that combines chopper stabilization techniques with a multi-path amplification structure. It is designed to suppress low-frequency noise and offset while achieving high-precision signal amplification. This type of amplifier is widely used in applications such as high-accuracy sensors, medical electronics, and precision instrumentation signal conditioning. The chopper-stabilized multi-path amplifier separates the amplifier into a high-frequency path with wide bandwidth and a low-frequency path with high gain, low offset, and low noise. The overall gain, offset, and noise of the amplifier are determined by the low-frequency path, while the high-frequency path provides wide bandwidth and fast dynamic response. In addition, stabilization techniques, such as Miller frequency compensation, are employed to ensure adequate phase margin and to prevent oscillation in closed-loop feedback.

Although the chopper-stabilized multi-path amplifier can reduce low-frequency offset voltage and noise through chopper modulation, residual modulated 1/f noise and offset appear at the amplifier output in the form of output ripple. The ripple resembles a square wave superimposed on the desired signal, and its presence at the output directly degrades measurement accuracy and the quality of the amplifier output. Furthermore, the ripple increases the noise level of subsequent-stage input signals, reducing the signal-to-noise ratio in precision data acquisition or sensor signal processing. Consequently, ripple reduction is a key design challenge in the chopper-stabilized multi-path amplifier.

To suppress ripple in a chopper-stabilized multi-path amplifier, several ripple reduction techniques have been disclosed: (1) After chopper modulation at the first-stage amplifier, a low-pass filter or a notch filter is employed to selectively attenuate ripple components that are modulated to the chopping frequency, thereby reducing output ripple (R. Burt and J. Zhang, “A Micropower Chopper-Stabilized Operational Amplifier Using a SC Notch Filter With Synchronous Integration Inside the Continuous-Time Signal Path,” in IEEE Journal of Solid-State Circuits, vol. 41, no. 12, pp. 2729-2736 December 2006); (2) A ripple reduction loop (RRL) is employed, in which a feedback-based suppression mechanism is used to detect the ripple component and to generate a corresponding offset compensation signal, thereby reducing the output ripple of the amplifier (R. Wu, K. A. A. Makinwa and J. H. Huijsing, “A Chopper Current-Feedback Instrumentation Amplifier With a 1 mHz 1/f Noise Corner and an AC-Coupled Ripple Reduction Loop,” in IEEE Journal of Solid-State Circuits, vol. 44, no. 12, pp. 3232-3243 December 2009); (3) A high-pass filter is employed to selectively remove the residue low-frequency voltage induced by offset, thereby preventing such voltage from being modulated by the chopper operation and consequently suppressing output ripple (Qu, Q. Pan, L. Liu, X. Zeng, Z. Hong and J. Xu, “A 1.8-GQ Input-Impedance 0.15-μV Input-Referred-Ripple Chopper Amplifier With Local Positive Feedback and SAR-Assisted Ripple Reduction,” in IEEE Journal of Solid-State Circuits, vol. 58, no. 3, pp. 796-805, March 2023); (4) The offset of the first-stage amplifier is calibrated using a digital calibration method, thereby reducing the offset and consequently suppressing the output ripple (J. Xu, R. F. Yazicioglu, B. Grundlehner, P. Harpe, K. A. A. Makinwa and C. Van Hoof, “A 160 μW 8-Channel Active Electrode System for EEG Monitoring,” in IEEE Transactions on Biomedical Circuits and Systems, vol. 5, no. 6, pp. 555-567, December 2011).

Currently, the following related research and patents address chopper-stabilized multi-path operational amplifier or chopper amplifier circuits and methods for ripple reduction:

The publication “A Micropower Chopper-CDS Operational Amplifier” (IEEE Journal of Solid-State Circuits, vol. 45, no. 12, pp. 2521-2529) describes a single-path amplifier circuit based on chopper-stabilized correlated double sampling (CDS). In this circuit, chopper modulation is combined with the CDS method, and the AC-coupling capacitor in the CDS path eliminates the offset voltage of the first-stage amplifier while enabling chopper demodulation. A prerequisite for proper operation is that the offset voltage of the first-stage amplifier does not saturate its output. In contrast, the present invention combines the chopper-stabilized correlated double sampling circuit with a multi-path amplifier, which achieves a better trade-off among noise, offset, and bandwidth compared with the single-path amplifier. Furthermore, the disclosed circuit redesigns the chopper CDS circuit by reusing the Miller compensation capacitors in the chopper-stabilized multi-path amplifier, while reducing one set of sampling capacitors and sampling switches compared with conventional CDS circuits. The offset calibration technique is employed to further suppress the output ripple while ensuring proper operation and the stability of the chopper-stabilized multi-path amplifier.

The publication “A 1.8-GΩ Input-Impedance 0.15-μV Input-Referred Ripple Chopper Amplifier With Local Positive Feedback and SAR-Assisted Ripple Reduction” (IEEE Journal of Solid-State Circuits, vol. 58, no. 3, pp. 796-805) describes a combination of high-pass filtering and successive-approximation-register (SAR)-based offset calibration technique. The technique utilizes an offset calibration circuit to prevent saturation of the first-stage amplifier while selectively filtering output ripple caused by offset through a conventional high-pass filter circuit. In contrast, the present invention adopts a novel chopper-stabilized correlated double sampling circuit based on Miller capacitor reuse to replace the conventional high-pass filter circuit, thereby suppressing output ripple and 1/f noise. The high-pass characteristic of the novel CDS circuit effectively suppresses output ripple and mitigates 1/f noise without requiring the large capacitors and resistors used in the high-pass filter of conventional chopper-stabilized multi-path amplifier designs. Consequently, the circuit and method reduce layout area, lower the drive current necessary for handling large capacitive loads, and decrease the power consumption. Furthermore, the circuit and method reduce the thermal noise associated with the large resistors of passive high-pass filters and thereby lowering the input-referred noise.

Chinese patent CN119051607A discloses a chopper instrumentation amplifier circuit that is configured to exhibit low output ripple. The circuit utilizes the common-mode rejection characteristics of a differential operational amplifier to mitigate interference caused by chopper switching noise, thereby addressing the issue of large output ripple. In contrast, the present invention employs a novel chopper correlated double sampling circuit with high-pass characteristics to suppress output ripple and 1/f noise, where the Miller compensation capacitor in the chopper-stabilized multi-path amplifier circuit is reused as the sampling capacitor of CDS circuit.

Chinese patent CN118962539A discloses a ripple reduction loop for canceling the Hall offset voltage, which utilizes a high-pass filter in the feedback path to filter out low-frequency Hall voltage while retaining the modulated high-frequency offset voltage. The offset voltage is then restored to a DC component through chopper switches and an integrator filter, and input to the negative terminal of an instrumentation amplifier to cancel the offset voltage. This methodology is classified within the aforementioned category of ripple reduction loop techniques. In contrast, the present invention utilizes the high-pass characteristic of a novel chopper correlated double sampling circuit to suppress output ripple. Furthermore, the offset calibration technique is employed to further suppress the output ripple while ensuring proper operation and the stability of the chopper-stabilized multi-path amplifier.

Chinese patent CN109818583A discloses a single-path chopper amplifier incorporating a high-pass filter for suppressing chopper ripple. The method detects the low-frequency content of the amplified differential signal and generates a corresponding compensation signal supplied to the first-stage gain circuit, thereby reducing low-frequency noise and input offset voltage. In contrast, the present invention utilizes the high-pass characteristic of a novel chopper correlated double sampling circuit to suppress output ripple and 1/f noise in the chopper-stabilized multi-path amplifier. Furthermore, the disclosed circuit redesigns the chopper CDS circuit by reusing the Miller compensation capacitors in the chopper-stabilized multi-path amplifier, thereby reducing one set of sampling capacitors and sampling switches compared with conventional CDS circuits.

In summary, although various circuits and techniques have been developed to suppress ripple in chopper-stabilized multi-path amplifiers or chopper amplifiers, none of the prior art discloses or suggests the novel chopper-stabilized correlated double sampling multi-path amplifier circuit and method based on Miller capacitor reuse of the present invention. To the best of the applicant's knowledge, no prior disclosure of designing a chopper correlated double sampling circuit by utilizing the Miller compensation capacitors, nor does any prior art disclosure of applying such a novel chopper correlated double sampling circuit to a chopper-stabilized multi-path amplifier.

### SUMMARY OF THE INVENTION

The objective of this invention is to address the output ripple caused by residual modulated 1/f noise and offset in chopper-stabilized multi-path amplifiers, while preserving both stability and low-offset performance. A novel chopper-stabilized correlated double sampling multi-path amplifier circuit and method based on Miller capacitor reuse is disclosed. The circuit and method exploit the Miller compensation capacitors as the correlated double sampling elements, which inherently provide discrete-time high-pass filter on DC offset, thereby not only maintaining the stability but also suppressing the offset, 1/f noise, and output ripple. The offset calibration technique is employed to further suppress the output ripple while ensuring proper operation of the CDS circuit. Consequently, the CDS circuit is implemented without an extra set of sampling capacitors and switches as in conventional CDS circuits. Furthermore, the high-pass characteristic of the novel CDS circuit effectively suppresses output ripple, without requiring the large capacitors and resistors used in high-pass filter of conventional chopper-stabilized multi-path amplifier designs. Hence, the circuit and method reduce layout area, lower the drive current necessary for handling large capacitive loads, and decrease the power consumption.

To achieve the above objectives, this invention provides the following technical solutions on circuit and method.

The chopper-stabilized correlated double sampling multi-path amplifier circuit comprises the analog differential input port Vᵢₙ, the chopper circuit CH₁, the calibration common-mode voltage input port V_{icm1}, the offset calibration switch group SW of the first-stage amplifier Gₘ₁, the Gₘ₁ offset calibration clock Φ_{cal}, the first-stage amplifier Gₘ₁, the offset calibration circuit of Gₘ₁, the CDS circuit, the second-stage amplifier Gₘ₂, the output-stage amplifier Gₘ₄, the second-stage Miller compensation capacitor group, the auxiliary amplifier Gₘ₃, and the output port Vₒᵤₜ; the offset calibration switch group SW of the first-stage amplifier Gₘ₁ comprises switches SW_{c0}, SW_{c1}, SW_{c2}, and SW_{c3}; and the second-stage Miller compensation capacitor group comprises capacitors C_{M20} and C_{M21}; the analog differential input port Vᵢₙ is connected to the input of the chopper circuit CH₁ and to the input of the auxiliary amplifier Gₘ₃; the input of the first-stage amplifier Gₘ₁ is connected, through switches SW_{c1} and SW_{c2}, to the calibration common-mode voltage input port V_{icm1}, and is further connected, through switches SW_{c0} and SW_{c3}, to an output of the chopper circuit CH₁; the Gₘ₁ offset calibration clock Φ_{cal} serves as operating clock for the Gₘ₁ offset calibration switch SW group to control switching operations thereof; the output of the first-stage amplifier Gₘ₁ and the input of the Gₘ₁ offset calibration circuit are connected to inputs of the CDS circuit, and the output of the Gₘ₁ offset calibration circuit is connected to the Cal port of the first-stage amplifier Gₘ₁; the outputs Vₒ₁ and Vₒ₂ of the CDS circuit are connected to inputs of the second-stage amplifier Gₘ₂, and the output Vₒ₃ of the CDS circuit is connected to the output port Vₒᵤₜ, the input of the output-stage amplifier Gₘ₄ is connected to the output of the second-stage amplifier Gₘ₂ and to the output of the auxiliary amplifier Gₘ₃; the capacitors C_{M20} and C_{M21} are connected between the input and the output of the output-stage amplifier Gₘ₄ respectively; the output of the output-stage amplifier Gₘ₄ is connected to the output port Vₒᵤₜ.

The CDS circuit comprises the double sampling capacitor group, the sampling switch SW group, the sampling clock Φ₁, the sampling common-mode voltage input port V_{icm2}, and the first-stage Miller compensation capacitor group; the double sampling capacitor group comprises capacitors C_{cds0}, C_{cds1}, C_{cds2}, and C_{cds3}; the sampling switch SW group comprises sampling switches SW₀~SW₇; the first-stage Miller compensation capacitor group comprises capacitors C_{M10} and C_{M11}; the Vᵢₙ and Vᵢₚ input ports of the CDS circuit are respectively connected to the negative and positive output terminals of the first-stage amplifier Gₘ₁; the Vᵢₙ input port of the CDS circuit is connected, through capacitor C_{cds0} and the sampling switch SW₀, to the input of the second-stage amplifier Gₘ₂ and to a terminal of capacitor C_{M11}, and is further connected, through capacitor C_{cds0} and sampling switch SW₄, to the sampling common-mode voltage input port V_{icm2}, thereby forming the first signal path of the CDS circuit; the Vᵢₙ input port of the CDS circuit is connected, through capacitor C_{cds1} and sampling switch SW₁, to the sampling common-mode voltage input port V_{icm2}, and is further connected, through capacitor C_{cds1} and sampling switch SW₅, to the input of the second-stage amplifier Gₘ₂ and to one terminal of capacitor C_{M10}, thereby forming the second signal path of the CDS circuit; the Vᵢₚ input port of the CDS circuit is connected, through capacitor C_{cds2} and sampling switch SW₂, to the input of the second-stage amplifier Gₘ₂ and to one terminal of capacitor C_{M10}, and is further connected, through capacitor C_{cds2} and sampling switch SW₆, to the sampling common-mode voltage input port V_{icm2}, thereby forming the third signal path of the CDS circuit; the Vᵢₚ input port of the CDS circuit is connected, through capacitor C_{cds3} and sampling switch SW₃, to the sampling common-mode voltage input port V_{icm2}, and is further connected, through capacitor C_{cds3} and sampling switch SW₇, to the input of the second-stage amplifier Gₘ₂ and to one terminal of capacitor C_{M11}, thereby forming a fourth signal path of the CDS circuit; during the Φ₁ phase, the first and third signal paths perform sampling and deliver the signal to an input of the second-stage amplifier Gₘ₂, while the second and fourth signal paths are connected to the sampling common-mode voltage input port V_{icm2} for reset; during the Φ̅₁ phase, the first and third signal paths are connected to the sampling common-mode voltage input port V_{icm2} for reset, while the second and fourth signal paths perform sampling and deliver signal to the input of the second-stage amplifier Gₘ₂; one terminal of capacitor C_{M10} is connected to the input of the second-stage amplifier Gₘ₂, and another terminal of capacitor C_{M10} is connected to an output of the output-stage amplifier Gₘ₄; one terminal of capacitor C_{M11} is connected to the input of the second-stage amplifier Gₘ₂, and another terminal of capacitor C_{M11} is connected to ground.

The offset calibration circuit of Gₘ₁ comprises a dynamic comparator, a successive approximation logic circuit, and a current-mode DAC; the input of the dynamic comparator is connected to the output of the first-stage amplifier Gₘ₁; the successive approximation logic circuit receives the output of the dynamic comparator and generates the corresponding calibration code to the input of the current-mode DAC; the output of the current-mode DAC is connected to the Cal port of the first-stage amplifier Gₘ₁.

The CDS circuit operates according to the following timing sequence:
1, During the Φ̅₁ phase, a signal at the Vᵢₚ input port of the CDS circuit is connected, through capacitor C_{cds2} and sampling switch SW₆, to the sampling common-mode voltage input port V_{icm2}, the signal at the Vᵢₚ is:

$${V}_{ip} ( {\overline{Φ}}_{1} ) = {A}_{1} [ - {V}_{in} ( {\overline{Φ}}_{1} ) + {V}_{os} + {V}_{n} ( {\overline{Φ}}_{1} ) ] \qquad ( 1 )$$

where Vᵢₙ is the analog input signal, Vₒₛ and Vₙ respectively represent the input offset voltage and input-referred noise of the first-stage amplifier Gₘ₁, and A₁ is the gain of the first-stage amplifier Gₘ₁; during the Φ̅₁ phase, the charge Q_{cds2} on capacitor C_{cds2} is given by:

$${Q}_{cds 2} ( {\overline{Φ}}_{1} ) = {C}_{cds 2} [ {V}_{ip} ( {\overline{Φ}}_{1} ) - {V}_{icm 2} ] \qquad ( 2 )$$

where V_{icm2} is the sampling input common-mode voltage;
2, During the Φ₁ phase, a signal at the Vᵢₚ input port of the correlated double sampling circuit is connected, through capacitor C_{cds2} and sampling switch SW₂, to one terminal of capacitor C_{M10} and to an input of the second-stage amplifier Gₘ₂; since capacitor C_{M10} bridges between the input of the second-stage amplifier Gₘ₂ and the output of the output-stage amplifier Gₘ₄, according to the Miller's theorem, it can be equivalent to a sampling capacitor C_{M1a}=(1+A₂A₄) C_{M10} is connected to the input of the second-stage amplifier Gₘ₂, and a loading capacitor C_{M1b}=[(1+A₂A₄) C_{M10}]/A₂A₄ is connected to the output of the output-stage amplifier Gₘ₄, where A₂ and A₄ are the gains of the second-stage amplifier Gₘ₂ and the output-stage amplifier Gₘ₄, respectively; according to the law of charge conservation, the sum of the charges on C_{cds2} and C_{M1a} during the Φ₁ phase should be equal to the charge on C_{cds2} during the Φ̅₁ phase, that is:

$${Q}_{cds 2} ( {\overline{Φ}}_{1} ) = {Q}_{cds 2} ( {\overline{Φ}}_{1} ) + {Q}_{{C}_{M 1 a}} ( {\overline{Φ}}_{1} ) \qquad ( 3 )$$

where Q_{C}_{_{M1a}} (Φ1)=−(1+A₂A₄)C_{M10}[V_{cs}(Φ₁)−V_{icm2}] is the charge on capacitor C_{M1a} during the Φ₁ phase, V_{cs} is the voltage across capacitor C_{M1a}, and Q_{cds2}(Φ₁)=C_{cds2}[Vᵢₚ(Φ₁)−V_{cs}(Φ₁)] is the charge on capacitor C_{cds2} during the Φ₁ phase; substituting them into Equation (3) and rearranging yields:

$${V}_{c s} ( {Φ}_{1} ) = \frac{{C}_{cds 2} ( {V}_{i p} ( {Φ}_{1} ) - {V}_{i p} ( {\overline{Φ}}_{1} ) )}{{C}_{cds 2} + ( 1 + {A}_{2} {A}_{4} ) {C}_{M 10}} + {V}_{icm 2} \qquad ( 4 )$$

during Φ1 phase, the chopper circuit CH₁ inverts the polarity of Vᵢₙ, therefore, it follows that:

$${V}_{i p} ( {Φ}_{1} ) = {A}_{1} [ {V}_{i n} ( {Φ}_{1} ) + {V}_{o s} + {V}_{n} ( {Φ}_{1} ) ] \qquad ( 5 )$$

by combining Equations (1), (4), and (5), it follows that:

$${V}_{c s} ( {Φ}_{1} ) = \frac{{A}_{1} {C}_{cds 2} ( {V}_{i n} ( {\overline{Φ}}_{1} ) + {V}_{i n} ( {Φ}_{1} ) - {V}_{n} ( {\overline{Φ}}_{1} ) + {V}_{n} ( {Φ}_{1} ) )}{{C}_{cds 2} + ( 1 + {A}_{2} {A}_{4} ) {C}_{M 10}} + {V}_{icm 2} \qquad ( 6 )$$

From Equation (6), it can be seen that the transfer function of the input signal Vᵢₙ is 1+z⁻¹, which corresponds to a low-pass characteristic; the transfer function of the input-referred noise Vₙ is 1−z⁻¹, which corresponds to a high-pass characteristic; and the input offset voltage Vₒₛ is canceled; These observations demonstrate that the disclosed CDS circuit is capable of filtering and reducing input-referred noise and offset voltage, thereby suppressing output ripple.

Compared with the prior art, the present invention achieves the following notable technical advantages:
1, A novel chopper-stabilized correlated double sampling multi-path amplifier circuit based on Miller capacitor reuse, where the circuit and method exploits the Miller compensation capacitor as a CDS element, which inherently provides discrete-time high-pass filter on DC offset, thereby not only maintaining the stability but also suppressing the offset, 1/f noise, and output ripple.
2, The high-pass characteristic of the novel CDS circuit effectively suppresses output ripple and mitigates 1/f noise without requiring the large capacitors and resistors used in the high-pass filter of conventional chopper-stabilized multi-path amplifier designs. The thermal noise introduced by the large resistors is significantly reduced as well, leading to an improved input-referred noise spectral density. Consequently, this circuit and method reduce layout area, lower the drive current necessary for handling large capacitive loads, and decrease the power consumption.
3, A novel chopper-stabilized correlated double sampling multi-path amplifier circuit based on Miller capacitor reuse; Compared with conventional CDS circuits, the disclosed CDS circuit based on Miller capacitor reuse reduces one set of sampling capacitors and sampling switches, thereby simplifying the circuit architecture and reducing layout area.

### BRIEF DESCRIPTION OF THE DRAWINGS

The patent or application file contains at least one drawing executed in color. Copies of this patent or patent application publication with color drawings will be provided by the Office upon request and payment of the necessary fee.

FIG. 1 illustrates a block diagram of the novel chopper-stabilized correlated double sampling multi-path amplifier circuit based on Miller capacitor reuse of the present invention.

FIG. 2 illustrates the equivalent circuit and the operating phase diagram of the CDS circuit of the present invention.

FIG. 3 illustrates the timing diagram of the waveforms of the offset calibration circuit of Gₘ₁ in the present invention.

FIG. 4 illustrates a comparison of the output ripple waveform of the present invention relative to other methods.

FIG. 5 illustrates a comparison of the input-referred offset voltage between the chopper-stabilized CDS multi-path amplifier of the present invention and a conventional chopper-stabilized multi-path amplifier;

FIG. 6 illustrates a comparison of the input-referred ripple between the chopper-stabilized CDS multi-path amplifier of the present invention and a conventional chopper-stabilized multi-path amplifier.

FIG. 7 illustrates a comparison of the input-referred noise spectral density of the chopper-stabilized multi-path amplifier of the present invention, with and without the chopper-stabilized CDS technique.

### DETAILED DESCRIPTION OF THE INVENTION

In order to make the objectives, technical solutions, and advantages of the present invention more clearly understood, the following embodiments are described in further detail with reference to the accompanying drawings. It should be understood that the specific embodiments described herein are provided merely for purposes of illustration and explanation, and are not intended to limit the present invention. Any modifications, equivalent substitutions, or improvements made within the spirit and principles of the circuit architecture and methods of the present invention shall fall within the scope of the present invention.

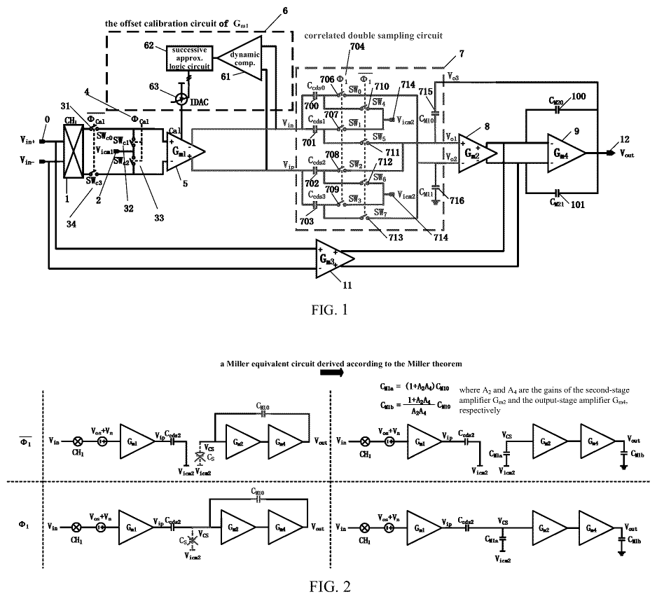

Referring to FIG. 1, the embodiment of the chopper-stabilized correlated double sampling multi-path amplifier circuit based on Miller capacitor reuse comprises the analog differential input port Vᵢₙ 0, the chopper circuit CH₁ 1, the calibration common-mode voltage input port V_{icm1} 2, the offset calibration switch group SW of the first-stage amplifier Gₘ₁, the Gₘ₁ offset calibration clock Φ_{cal} 4, the first-stage amplifier Gₘ₁ 5, the offset calibration circuit of Gₘ₁ 6, the CDS circuit 7, the second-stage amplifier Gₘ₂ 8, the output-stage amplifier Gₘ₄ 9, the second-stage Miller compensation capacitor group, the auxiliary amplifier Gₘ₃ 11, and the output port Vₒᵤₜ 12. The offset calibration switch group SW of the first-stage amplifier Gₘ₁ comprises switches SW_{c0} 31, SW_{c1} 32, SW_{c2} 33, and SW_{c3} 34; the second-stage Miller compensation capacitor group comprises capacitors C_{M20} 100 and C_{M21} 101.

The analog differential input port Vᵢₙ 0 is connected to the input of the chopper circuit CH₁ 1 and to the input of the auxiliary amplifier Gₘ₃ 11; the input of the first-stage amplifier Gₘ₁ 5 is connected, through switches SW_{c1} 32 and SW_{c2} 33, to the calibration common-mode voltage input port V_{icm1} 2, and is further connected, through switches SW_{c0} 31 and SW_{c3} 34, to an output of the chopper circuit CH₁ 1; the Gₘ₁ offset calibration clock Φ_{cal} 4 serve as operating clock for the Gₘ₁ offset calibration switch SW group to control switching operations thereof; the output of the first-stage amplifier Gₘ₁ 5 and the input of the Gₘ₁ offset calibration circuit 6 are connected to inputs of the CDS circuit 7, and the output of the Gₘ₁ offset calibration circuit 6 is connected to the Cal port of the first-stage amplifier Gₘ₁ 5; the Gₘ₁ offset calibration circuit 6 is configured to detect and calibrate the offset voltage of the first-stage amplifier Gₘ₁ 5; the outputs Vₒ₁ and Vₒ₂ of the CDS circuit 7 are connected to inputs of the second-stage amplifier Gₘ₂ 8, and the output Vₒ₃ of the CDS circuit 7 is connected to the output port Vₒᵤₜ 12; the input of the output-stage amplifier Gₘ₄ 9 is connected to the output of the second-stage amplifier Gₘ₂ 8 and to the output of the auxiliary amplifier Gₘ₃ 11; the second-stage amplifier Gₘ₂ 8 is configured to further amplify the sampled signal; the capacitors C_{M20} 100 and C_{M21} 101 are connected between the input and the output of the output-stage amplifier Gₘ₄ 9 respectively; the output of the output-stage amplifier Gₘ₄ 9 is connected to the output port Vₒᵤₜ 12; the output-stage amplifier Gₘ₄ 9 is configured to provide the final amplified output signal.

The CDS circuit 7 comprises the double sampling capacitor group, the sampling switch SW group, the sampling clock Φ₁ 704, the sampling common-mode voltage input port V_{icm2} 714, and the first-stage Miller compensation capacitor group; the double sampling capacitor group comprises capacitors C_{cds0} 700, C_{cds1} 701, C_{cds2} 702, and C_{cds3} 703; the sampling switch SW group comprises sampling switches SW₀ 706, SW₁ 707, SW₂ 708, SW₃ 709, SW₄ 710, SW₅ 711, SW₆ 712, SW₇ 713; the first-stage Miller compensation capacitor group comprises capacitors C_{M10} 715 and C_{M11} 716;

The Vᵢₙ and Vᵢₚ input ports of the CDS circuit 7 are respectively connected to the negative and positive output terminals of the first-stage amplifier Gₘ₁ 5; the Vᵢₙ input port of the CDS circuit 7 is connected, through capacitor C_{cds0} 700 and the sampling switch SW₀ 706, to the input of the second-stage amplifier Gₘ₂ 8 and to a terminal of capacitor C_{M11} 716, and is further connected, through capacitor C_{cds0} 700 and sampling switch SW₄ 710, to the sampling common-mode voltage input port V_{icm2} 714, thereby forming the first signal path of the CDS circuit; The Vᵢₙ input port of the CDS circuit 7 is connected, through capacitor C_{cds1} 701 and sampling switch SW₁ 707, to the sampling common-mode voltage input port V_{icm2} 714, and is further connected, through capacitor C_{cds1} 701 and sampling switch SW₅ 711, to the input of the second-stage amplifier Gₘ₂ 8 and to one terminal of capacitor C_{M10} 715, thereby forming the second signal path of the CDS circuit; The Vᵢₚ input port of the CDS circuit 7 is connected, through capacitor C_{cds2} 702 and sampling switch SW₂ 708, to the input of the second-stage amplifier Gₘ₂ 8 and to one terminal of capacitor C_{M10} 715, and is further connected, through capacitor C_{cds2} 702 and sampling switch SW₆ 712, to the sampling common-mode voltage input port V_{icm2} 714, thereby forming the third signal path of the CDS circuit; the Vᵢₚ input port of the CDS circuit 7 is connected, through capacitor C_{cds3} 703 and sampling switch SW₃ 709, to the sampling common-mode voltage input port V_{icm2} 714, and is further connected, through capacitor C_{cds3} 703 and sampling switch SW₇ 713, to the input of the second-stage amplifier Gₘ₂ 8 and to one terminal of capacitor C_{M11} 716, thereby forming a fourth signal path of the CDS circuit.

During the Φ₁ phase, the first and third signal paths perform sampling and deliver the signal to an input of the second-stage amplifier Gₘ₂ 8, while the second and fourth signal paths are connected to the sampling common-mode voltage input port V_{icm2} 714 for reset; during the Φ̅₁ phase, the first and third signal paths are connected to the sampling common-mode voltage input port V_{icm2} 714 for reset, while the second and fourth signal paths perform sampling and delivers signal to the input of the second-stage amplifier Gₘ₂ 8; this alternating operation ensures that the signal continuity is maintained even during sampling and charge transfer, thereby improving the overall accuracy and stability of the amplifier circuit; one terminal of capacitor C_{M10} 715 is connected to the input of the second-stage amplifier Gₘ₂ 8, and another terminal of capacitor C_{M10} 715 is connected to an output of the output-stage amplifier Gₘ₄ 9; one terminal of capacitor C_{M11} 716 is connected to the input of the second-stage amplifier Gₘ₂ 8, and another terminal of capacitor C_{M11} 716 is connected to ground.

The offset calibration circuit of Gₘ₁ 6 comprises a dynamic comparator 61, a successive approximation logic circuit 62, and a current-mode DAC 63; the input of the dynamic comparator 61 is connected to the output of the first-stage amplifier Gₘ₁ 5; the successive approximation logic circuit 62 receives the output of the dynamic comparator 61 and generates the corresponding calibration code to the input of the current-mode DAC 63; the output of the current-mode DAC 63 is connected to the Cal port of the first-stage amplifier Gₘ₁ 5.

The present invention discloses a novel chopper-stabilized correlated double sampling multi-path amplifier circuit and method based on Miller capacitor reuse. By exploiting the Miller compensation capacitors as the correlated double-sampling elements, which inherently provide discrete-time high-pass filter on DC offset, the disclosed circuit and method not only maintain the stability but also lower the offset, reduce the input-referred noise spectral density, and suppress the output ripple. Compared with conventional correlated double sampling circuits, the disclosed circuit and method reduce one set of sampling capacitors and sampling switches. Furthermore, the high-pass characteristic of the novel correlated double sampling circuit effectively suppresses output ripple and mitigates 1/f noise without requiring the large capacitors and resistors used in the high-pass filter of conventional chopper-stabilized multi-path amplifier designs. The thermal noise introduced by the large resistors is significantly reduced as well, leading to an improved input-referred noise spectral density. Moreover, the present invention provides a reduced layout area and lowers the driving current necessary for large capacitive loads, thereby reducing the total power consumption.

FIG. 2 illustrates the equivalent circuit and the operating phase diagram of the CDS circuit of the present invention; the operating phase of the CDS circuit is as follows:
1, During the Φ̅₁ phase, a signal at the Vᵢₚ input port of the CDS circuit is connected, through capacitor C_{cds2} and sampling switch SW₆, to the sampling common-mode voltage input port V_{icm2}, the signal at the Vᵢₚ is:

$${V}_{i p} ( {\overline{Φ}}_{1} ) = {A}_{1} [ - {V}_{i n} ( {\overline{Φ}}_{1} ) + {V}_{o s} + {V}_{n} ( {\overline{Φ}}_{1} ) ] \qquad ( 1 )$$

where Vᵢₙ is the analog input signal, Vₒₛ and Vₙ respectively represent the input offset voltage and input-referred noise of the first-stage amplifier Gₘ₁, and A₁ is the gain of the first-stage amplifier Gₘ₁; during the Φ̅₁ phase, the charge Q_{cds2} on capacitor C_{cds2} is given by:

$${Q}_{cds 2} ( {\overline{Φ}}_{1} ) = {C}_{cds 2} [ {V}_{i p} ( {\overline{Φ}}_{1} ) - {V}_{icm 2} ] \qquad ( 2 )$$

where V_{icm2} is the sampling input common-mode voltage;
2. During the Φ1 phase, a signal at the Vᵢₚ input port of the correlated double sampling circuit is connected, through capacitor C_{cds2} and sampling switch SW₂, to one terminal of capacitor C_{M10} and to an input of the second-stage amplifier Gₘ₂; since capacitor C_{M10} bridges between the input of the second-stage amplifier Gₘ₂ and the output of the output-stage amplifier Gₘ₄, according to the Miller's theorem, it can be equivalent to a sampling capacitor C_{M1a} (1+A₂A₄) C_{M10} is connected to the input of the second-stage amplifier Gₘ₂, and a loading capacitor C_{M1b}=[(1+A₂A₄) C_{M10}]/A₂A₄ is connected to the output of the output-stage amplifier Gₘ₄, where A₂ and A₄ are the gains of the second-stage amplifier Gₘ₂ and the output-stage amplifier Gₘ₄, respectively; according to the law of charge conservation, the sum of the charges on C_{cds2} and C_{M1a} during the Φ₁ phase should be equal to the charge on C_{cds2} during the Φ̅₁ phase, that is:

$${Q}_{cds 2} ( {\overline{Φ}}_{1} ) = {Q}_{cds 2} ( {Φ}_{1} ) + {Q}_{{C}_{M 1 a}} ( {Φ}_{1} ) \qquad ( 3 )$$

where Q_{C}_{_{M1a}}(Φ₁)=−(1+A₂A₄)C_{M10}[V_{cs}(Φ₁)−V_{icm2}] is the charge on capacitor C_{M1a} during the Φ₁ phase, V_{cs} is the voltage across capacitor C_{M1a}, and Q_{cds2}(Φ₁)=C_{cds2}[Vᵢₚ(Φ₁)−V_{cs} (Φ₁)] is the charge on capacitor C_{cds2} during the Φ₁ phase; substituting them into Equation (3) and rearranging yields:

$${V}_{c s} ( {Φ}_{1} ) = \frac{{C}_{cds 2} ( {V}_{i p} ( {Φ}_{1} ) - {V}_{i p} ( {\overline{Φ}}_{1} ) )}{{C}_{cds 2} + ( 1 + {A}_{2} {A}_{4} ) {C}_{M 10}} + {V}_{icm 2} \qquad ( 4 )$$

during Φ₁ phase, the chopper circuit CH₁ inverts the polarity of Vᵢₙ, therefore, it follows that:

$${V}_{i p} ( {Φ}_{1} ) = {A}_{1} [ {V}_{i n} ( {Φ}_{1} ) + {V}_{o s} + {V}_{n} ( {Φ}_{1} ) ] \qquad ( 5 )$$

by combining Equations (1), (4), and (5), it follows that:

$${V}_{c s} ( {Φ}_{1} ) = \frac{{A}_{1} {C}_{c d s 2} ( {V}_{i n} ( {\overline{Φ}}_{1} ) + {V}_{i n} ( {Φ}_{1} ) - {V}_{n} ( {\overline{Φ}}_{1} ) + {V}_{n} ( {Φ}_{1} ) )}{{C}_{cds 2} + ( 1 + {A}_{2} {A}_{4} ) {C}_{M 10}} + {V}_{icm 2} \qquad ( 6 )$$

From Equation (6), it can be seen that the transfer function of the input signal Vᵢₙ is 1+z⁻¹, which corresponds to a low-pass characteristic; the transfer function of the input-referred noise Vₙ is 1−z⁻¹, which corresponds to a high-pass characteristic; and the input offset voltage Vₒₛ is canceled; These observations demonstrate that the disclosed CDS circuit is capable of filtering and reducing input-referred noise and offset voltage, thereby suppressing output ripple.

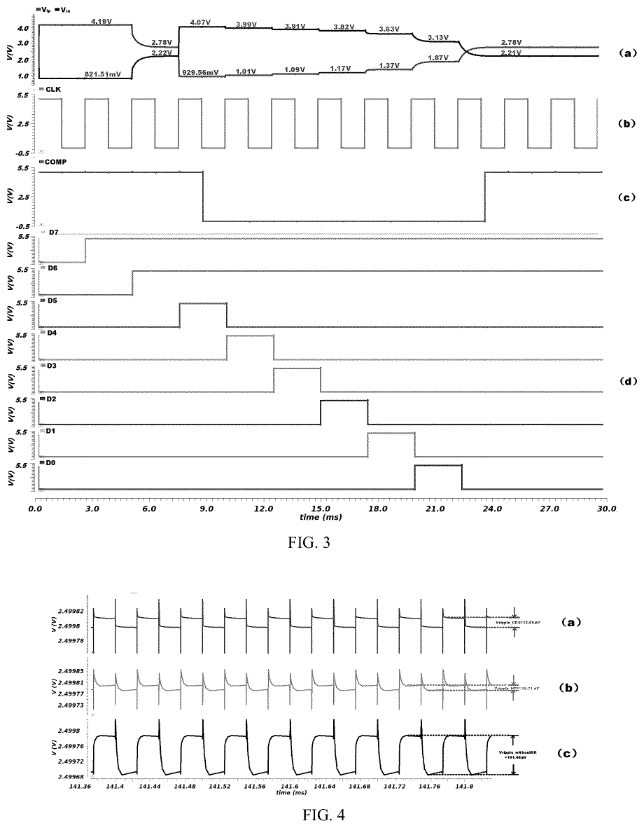

FIG. 3 illustrates the timing diagram of the waveforms of the offset calibration circuit of Gₘ₁ in the present invention; FIG. 3(a) shows the output voltages Vᵢₚ and Vᵢₙ of the first-stage amplifier Gₘ₁; FIG. 3(b) shows the clock CLK for dynamic comparator; FIG. 3(c) shows the output signal COMP of the dynamic comparator. FIG. 3(d) shows calibration codes D0~D7; during Φ_{cal} phase, switches SW_{c1} and SW_{c2} shown in FIG. 1 are closed, while switches SW_{c0} and SW_{c3} are open, such that the input of the first-stage amplifier Gₘ₁ is shorted to the calibration input common-mode voltage V_{icm1}; the dynamic comparator compares the difference between output voltages Vᵢₚ and Vᵢₙ of the first-stage amplifier Gₘ₁ at the falling edge of the clock CLK, as shown in FIG. 3(b); the difference reflects the output offset voltage of the first-stage amplifier Gₘ₁, and the comparison result is used to determine the calibration code D7, as illustrated in FIG. 3(c); at the subsequent falling edge of the clock CLK, the dynamic comparator again compares the output voltages Vᵢₚ and Vᵢₙ of the first-stage amplifier Gₘ₁; the corresponding comparison result is used to determine a calibration code D6; by repeating this process, calibration codes D0~D7 are generated, as shown in FIG. 3(d); the difference between output voltages Vᵢₚ and Vᵢₙ reflects the output offset voltage of the first-stage amplifier Gₘ₁. As shown in FIG. 3(a), the output offset voltage is reduced from 4.19 V−821.51 mV=3.37 V before calibration to 2.78 V−2.21 V=0.57 V after calibration using calibration codes D0~D7; this result demonstrates that the offset calibration circuit of Gₘ₁ in the present invention can significantly reduce the offset voltage, thereby ensuring that the first-stage amplifier Gₘ₁ does not saturate and operates normally.

FIG. 4 illustrates a comparison of the output ripple waveform of the present invention relative to other methods. The closed-loop gain of the simulated circuit is set to 100, and an offset voltage applied to a first-stage amplifier Gₘ₁ is set to 500 nV; FIG. 4(a) shows the output ripple waveform of the present invention; the output ripple is about 12.05 μV, which corresponds to an input-referred ripple of approximately 120.5 nV, determined by dividing the output ripple by the closed-loop gain; FIG. 4(b) shows the output ripple waveform obtained using the ripple reduction technique reported by T. Qu et al., IEEE J. Solid-State Circuits, vol. 58, no. 3, pp. 796-805, March 2023; the output ripple is approximately 15.71 μV, corresponding to an input-referred ripple of approximately 157.1 nV; FIG. 4(c) shows the output ripple waveform of a chopper-stabilized multi-path amplifier without any ripple reduction technique; the output ripple is about 101.48 μV, which corresponds to an input-referred ripple of approximately 1.01 μV; The comparative results in FIG. 4 demonstrate that the chopper-stabilized correlated double sampling multi-path amplifier circuit and method based on Miller capacitor reuse of the present invention can effectively suppress output ripple.

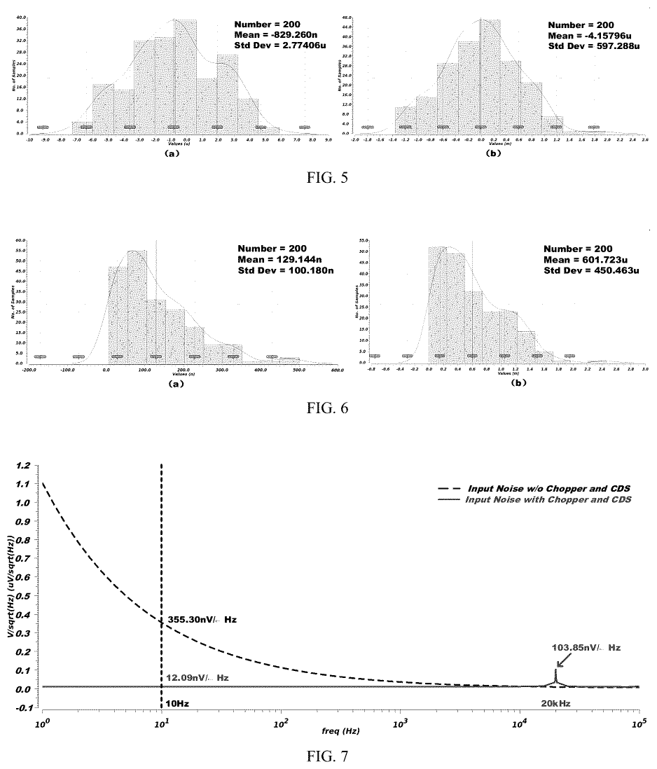

FIG. 5 illustrates a comparison of the input-referred offset voltage between the chopper-stabilized CDS multi-path amplifier of the present invention and a conventional chopper-stabilized multi-path amplifier. The closed-loop gain of the simulated circuit is set to 100, and 200 Monte Carlo simulations are performed on the input-referred offset voltage. In FIG. 5(a), the input-referred offset voltage histogram of the chopper-stabilized CDS multi-path amplifier of the present invention is illustrated, where the offset voltage is distributed over a range of [−9.15 μV, 7.28 μV], with a mean value of 829.26 nV and a standard deviation of 2.77 μV. In FIG. 5(b), the input-referred offset voltage histogram of the chopper-stabilized multi-path amplifier without a ripple suppression technique is illustrated, where the input-referred offset voltage is distributed over a range of [−1.79 mV, 1.79 mV], with a mean value of 4.16 μV and a standard deviation of 597.29 μV. These results demonstrate that the chopper-stabilized CDS multi-path amplifier of the present invention is capable of effectively reducing offset voltage.

FIG. 6 illustrates a comparison of the input-referred ripple between the chopper-stabilized CDS multi-path amplifier of the present invention and a conventional chopper-stabilized multi-path amplifier. The closed-loop gain of the simulated circuit is set to 100, and 200 Monte Carlo simulations are performed on the input-referred ripple. In FIG. 6(a), the input-referred ripple histogram of the chopper-stabilized CDS multi-path amplifier of the present invention is illustrated, where the ripple is distributed over a range of (0 V, 499.5 nV], with a mean value of 129.14 nV and a standard deviation of 100.18 nV. In FIG. 6(b), the input-referred ripple histogram of the chopper-stabilized multi-path amplifier without a ripple suppression technique is illustrated, where the input-referred ripple is distributed over a range of (0 V, 2.45 mV], with a mean value of 601.72 μV and a standard deviation of 450.46 μV. These results demonstrate that the chopper-stabilized CDS multi-path amplifier of the present invention is capable of substantially suppressing ripple.

FIG. 7 illustrates a comparison of the input-referred noise spectral density of the chopper-stabilized multi-path amplifier of the present invention, with and without the chopper-stabilized CDS technique. In FIG. 7, the dashed line represents the input-referred noise spectral density without the chopper-stabilized CDS technique, while the solid line represents the input-referred noise spectral density with the chopper-stabilized CDS technique; without the chopper-stabilized CDS technique, the input-referred noise spectral density is approximately 355.30 nV/\sqrt{Hz} at a frequency of 10 Hz; with the chopper-stabilized CDS technique, the input-referred noise spectral density is reduced to approximately 12.09 nV/\sqrt{Hz} at 10 Hz, representing a substantial improvement; the input-referred noise spectral density peak at 20 kHz in FIG. 7 is caused by the folding of low- and mid-frequency noise to the 20 kHz chopper frequency by the chopper-stabilized CDS. This comparison clearly demonstrates that the circuit and method of the present invention operate as intended and effectively lower the input-referred spectral noise density in the low- and mid-frequency bands.

The present invention discloses a novel chopper-stabilized correlated double sampling multi-path amplifier circuit and method based on Miller capacitor reuse. By exploiting the Miller compensation capacitors as the correlated double sampling elements, which inherently provides discrete-time high-pass filter on DC offset, the disclosed circuit and method not only maintain the stability but also lower the offset, reduce the input-referred noise spectral density, and suppress the output ripple. Compared with conventional correlated double sampling circuits, the disclosed circuit reduces one set of sampling capacitors and sampling switches. Furthermore, the high-pass characteristic of the novel correlated double sampling circuit effectively suppresses output ripple and mitigates 1/f noise without requiring the large capacitors and resistors used in the high-pass filter of conventional chopper-stabilized multi-path amplifier designs. The thermal noise introduced by the large resistors is significantly reduced as well, leading to an improved input-referred noise spectral density. Moreover, the present invention provides a reduced layout area and lowers the driving current necessary for large capacitive loads, thereby reducing the total power consumption. Theoretical analysis and circuit simulation results verify the aforementioned advantages of the present invention.

The foregoing embodiments are merely illustrative of the preferred implementations of the present invention and are not to be construed as limiting the scope of the invention. All modifications, equivalent variations, and improvements made within the spirit and principles of the invention shall fall within the scope of the appended claims.

1. A novel chopper-stabilized correlated double sampling multi-path amplifier circuit based on Miller capacitor reuse, wherein the circuit comprises: the analog differential input port Vᵢₙ, the chopper circuit CH₁, the calibration common-mode voltage input port V_{icm1}, the offset calibration switch group SW of the first-stage amplifier Gₘ₁, the Gₘ₁ offset calibration clock Φ_{cal}, the first-stage amplifier Gₘ₁, the offset calibration circuit of Gₘ₁, the correlated double sampling circuit, the second-stage amplifier Gₘ₂, the output-stage amplifier Gₘ₄, the second-stage Miller compensation capacitor group, the auxiliary amplifier Gₘ₃, and the output port Vₒᵤₜ,
the offset calibration switch group SW of the first-stage amplifier Gₘ₁ comprises switches SW_{c0}, SW_{c1}, SW_{c2}, and SW_{c3}; the second-stage Miller compensation capacitor group comprises capacitors C_{M20} and C_{M21};
the analog differential input port Vᵢₙ is connected to the input of the chopper circuit CH₁ and to the input of the auxiliary amplifier Gₘ₃; the input of the first-stage amplifier Gₘ₁ is connected, through switches SW_{c1} and SW_{c2}, to the calibration common-mode voltage input port V_{icm1}, and is further connected, through switches SW_{c0} and SW_{c3}, to an output of the chopper circuit CH₁; the Gₘ₁ offset calibration clock Φ_{cal} serves as operating clock for the Gₘ₁ offset calibration switch SW group to control switching operations thereof; the output of the first-stage amplifier Gₘ₁ and the input of the Gₘ₁ offset calibration circuit are connected to the input of the CDS circuit, and the output of the Gₘ₁ offset calibration circuit is connected to the Cal port of the first-stage amplifier Gₘ₁; the Vₒ₁ and Vₒ₂ output ports of the correlated double sampling circuit are connected to inputs of the second-stage amplifier Gₘ₂, and the output Vₒ₃ of the correlated double sampling circuit is connected to the output port Vₒᵤₜ, the input of the output-stage amplifier Gₘ₄ is connected to the output of the second-stage amplifier Gₘ₂ and to the output of the auxiliary amplifier Gₘ₃; the capacitors C_{M20} and C_{M21} are connected between the input and the output of the output-stage amplifier Gₘ₄ respectively; the output of the output-stage amplifier Gₘ₄ is connected to the output port Vₒᵤₜ.

2. The novel chopper-stabilized correlated double sampling multi-path amplifier circuit based on Miller capacitor reuse of claim 1, wherein the correlated double sampling circuit comprises the double sampling capacitor group, the sampling switch SW group, the sampling clock Φ₁, the sampling common-mode voltage input port V_{icm2}, and the first-stage Miller compensation capacitor group;
the double sampling capacitor group comprises capacitors C_{cds0}, C_{cds1}, C_{cds2}, and C_{cds3}; the sampling switch SW group comprises sampling switches SW₀~SW₇, the first-stage Miller compensation capacitor group comprises capacitors C_{M10} and C_{M11};
the Vᵢₙ and Vᵢₚ input ports of the correlated double sampling circuit are respectively connected to the negative and positive output terminals of the first-stage amplifier Gₘ₁; the Vᵢₙ input port of the correlated double sampling circuit is connected, through capacitor C_{cds0} and the sampling switch SW₀, to the input of the second-stage amplifier Gₘ₂ and to a terminal of capacitor C_{M11}, and is further connected, through capacitor C_{cds0} and sampling switch SW₄, to the sampling common-mode voltage input port V_{icm2}, thereby forming the first signal path of the correlated double sampling circuit; the Vᵢₙ input port of the correlated double sampling circuit is connected, through capacitor C_{cds1} and sampling switch SW₁, to the sampling common-mode voltage input port V_{icm2}, and is further connected, through capacitor C_{cds1} and sampling switch SW₅, to the input of the second-stage amplifier Gₘ₂ and to one terminal of capacitor C_{M10}, thereby forming the second signal path of the correlated double sampling circuit; the Vᵢₚ input port of the correlated double sampling circuit is connected, through capacitor C_{cds2} and sampling switch SW₂, to the input of the second-stage amplifier Gₘ₂ and to one terminal of capacitor C_{M10}, and is further connected, through capacitor C_{cds2} and sampling switch SW₆, to the sampling common-mode voltage input port V_{icm2}, thereby forming the third signal path of the correlated double sampling circuit; the Vᵢₚ input port of the correlated double sampling circuit is connected, through capacitor C_{cds3} and sampling switch SW₃, to the sampling common-mode voltage input port V_{icm2}, and is further connected, through capacitor C_{cds3} and sampling switch SW₇, to the input of the second-stage amplifier Gₘ₂ and to one terminal of capacitor C_{M11}, thereby forming a fourth signal path of the correlated double sampling circuit; during the Φ₁ phase, the first and third signal paths perform sampling and deliver the signal to an input of the second-stage amplifier Gₘ₂, while the second and fourth signal paths are connected to the sampling common-mode voltage input port V_{icm2} for reset; during the Φ̅₁ phase, the first and third signal paths are connected to the sampling common-mode voltage input port V_{icm2} for reset, while the second and fourth signal paths perform sampling and deliver signal to the input of the second-stage amplifier Gₘ₂; one terminal of capacitor C_{M10} is connected to the input of the second-stage amplifier Gₘ₂, and another terminal of capacitor C_{M10} is connected to an output of the output-stage amplifier Gₘ₄; one terminal of capacitor C_{M11} is connected to the input of the second-stage amplifier Gₘ₂, and another terminal of capacitor C_{M11} is connected to ground.

3. The novel chopper-stabilized correlated double sampling multi-path amplifier circuit based on Miller capacitor reuse of claim 1, wherein the offset calibration circuit of Gₘ₁ comprises a dynamic comparator, a successive approximation logic circuit, and a current-mode DAC; the input of the dynamic comparator is connected to the output of the first-stage amplifier Gₘ₁; the successive approximation logic circuit receives the output of the dynamic comparator and generates the corresponding calibration code to the input of the current-mode DAC; the output of the current-mode DAC is connected to the Cal port of the first-stage amplifier Gₘ₁.

4. The novel chopper-stabilized correlated double sampling multi-path amplifier circuit based on Miller capacitor reuse of claim 2, wherein the operating timing of the correlated double sampling circuit includes a phase and a Φ̅₁ phase, during the Φ₁ phase, a signal at the Vᵢₚ input port of the correlated double sampling circuit is connected, through capacitor C_{cds2} and sampling switch SW₆, to the sampling common-mode voltage input port V_{icm2}, the signal at the Vᵢₚ is:
$${V}_{i p} ( {\overline{Φ}}_{1} ) = {A}_{1} [ - {V}_{i n} ( {\overline{Φ}}_{1} ) + {V}_{o s} + {V}_{n} ( {\overline{Φ}}_{1} ) ] ; \qquad ( 1 )$$
where Vᵢₙ is the analog input signal, Vₒₛ and Vₙ respectively represent the input offset voltage and input-referred noise of the first-stage amplifier Gₘ₁, and A₁ is the gain of the first-stage amplifier Gₘ₁; during the Φ̅₁ phase, the charge Q_{cds2} on capacitor C_{cds2} is given by:
$${Q}_{cds 2} ( {\overline{Φ}}_{1} ) = {C}_{cds 2} [ {V}_{i p} ( {\overline{Φ}}_{1} ) - {V}_{icm 2} ] ; \qquad ( 2 )$$
where V_{icm2} is the sampling input common-mode voltage; during the Φ1 phase, a signal at the Vᵢₚ input port of the correlated double sampling circuit is connected, through capacitor C_{cds2} and sampling switch SW₂, to one terminal of capacitor C_{M10} and to an input of the second-stage amplifier Gₘ₂; since capacitor C_{M10} bridges between the input of the second-stage amplifier Gₘ₂ and the output of the output-stage amplifier Gₘ₄, according to the Miller's theorem, it can be equivalent to a sampling capacitor C_{M1a}=(1+A₂A₄) C_{M10} is connected to the input of the second-stage amplifier Gₘ₂, and a loading capacitor C_{M1b}=[(1+A₂A₄) C_{M10}]/A₂A₄ is connected to the output of the output-stage amplifier Gₘ₄, where A₂ and A₄ are the gains of the second-stage amplifier Gₘ₂ and the output-stage amplifier Gₘ₄, respectively; according to the law of charge conservation, the sum of the charges on C_{cds2} and C_{M1a} during the Φ₁ phase should be equal to the charge on C_{cds2} during the Φ̅₁ phase, that is:
$${Q}_{cds 2} ( {\overline{Φ}}_{1} ) = {Q}_{cds 2} ( {Φ}_{1} ) + {Q}_{{C}_{M 1 a}} ( {Φ}_{1} ) ; \qquad ( 3 )$$
where Q_{C}_{_{M1a}}(Φ₁)=−(1+A₂A₄)C_{M10}[V_{cs}(Φ₁)−V_{icm2}] is the charge on capacitor C_{M1a} during the Φ₁ phase, V_{cs} is the voltage across capacitor C_{M1a}, and Q_{cds2}(1)=C_{cds2}[Vᵢₚ(Φ₁)−V_{cs}(Φ1)] is the charge on capacitor C_{cds2} during the Φ₁ phase; substituting them into Equation (3) and rearranging yields:
$${V}_{c s} ( {Φ}_{1} ) = \frac{{C}_{cds 2} ( {V}_{i p} ( {Φ}_{1} ) - {V}_{i p} ( {\overline{Φ}}_{1} ) )}{{C}_{cds 2} + ( 1 + {A}_{2} {A}_{4} ) {C}_{M 10}} + {V}_{i c m 2} ; \qquad ( 4 )$$
during Φ₁ phase, the chopper circuit CH₁ inverts the polarity of Vᵢₙ, therefore, it follows that:
$${V}_{i p} ( {Φ}_{1} ) = {A}_{1} [ {V}_{i n} ( {Φ}_{1} ) + {V}_{o s} + {V}_{n} ( {Φ}_{1} ) ] ; \qquad ( 5 )$$
by combining Equations (1), (4), and (5), it follows that:
$${V}_{c s} ( {Φ}_{1} ) = \frac{{A}_{1} {C}_{c d s 2} ( {V}_{i n} ( {\overline{Φ}}_{1} ) + {V}_{i n} ( {Φ}_{1} ) - {V}_{n} ( {\overline{Φ}}_{1} ) + {V}_{n} ( {Φ}_{1} ) )}{{C}_{cds 2} + ( 1 + {A}_{2} {A}_{4} ) {C}_{M 10}} + {V}_{icm 2} ; \qquad ( 6 )$$
from Equation (6), it can be seen that the transfer function of the input signal Vᵢₙ is 1+z⁻¹, which corresponds to a low-pass characteristic; the transfer function of the input-referred noise Vₙ is 1−z⁻¹, which corresponds to a high-pass characteristic; and the input offset voltage Vₒₛ is canceled; these observations demonstrate that the disclosed correlated double sampling circuit is capable of filtering and reducing input-referred noise and offset voltage, thereby suppressing output ripple.

5. The novel chopper-stabilized correlated double sampling multi-path amplifier circuit based on Miller capacitor reuse of claim 1, wherein the circuit and method exploit the Miller compensation capacitors as the correlated double sampling elements, which inherently provide discrete-time high-pass filter on DC offset, thereby not only maintaining the stability but also suppressing the offset, 1/f noise, and output ripple.
